(19) United States
(12) Patent Application Publication
(10) Pub. No.: US 2026/0101461 A1
(43) Pub. Date: Apr. 9, 2026

(54) Power Module Having Pressing Elements

(71) Applicant: Infineon Technologies AG, Neubiberg (DE)

(72) Inventors: Valeriano Cardi, Rome (IT); Marco Ludwig, Wickede/Ruhr (DE)

(21) Appl. No.: 18/909,236

(22) Filed: Oct. 8, 2024

(51) Int. Cl. H05K 5/00; H05K 5/02; H05K 7/20

(52) U.S. Cl. CPC H05K 5/15; H05K 5/0217; H05K 7/209

(57) ABSTRACT

A power module includes a substrate, a power semiconductor die, an enclosure, a first type pressing element, and a second type pressing element. The substrate and the enclosure delimit an interior space of the power module. The enclosure includes a first fastening side and a second fastening side, each including a fastening feature, and a first non-fastening side and a second non-fastening side that each intersects the first fastening side and the second fastening side. A first type pressing element is at the first fastening side and the second fastening side, and a second type pressing element is at the first non-fastening side and the second non-fastening side. Both types of pressing elements are configured to press against the substrate in a mounted state of the power module. The second type pressing element has a different geometrical structure and/or material composition than the first type pressing element.

### BACKGROUND

Demand for electronic modules for power applications, commonly referred to as power modules, continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled such power modules to be manufactured with advantageous features such as smaller footprint, higher voltage and current capabilities, and faster switching speeds.

As power modules become smaller and/or deliver higher currents, efficient heat dissipation by the power module becomes particularly important to ensuring acceptable reliability and lifetime. In some applications, heat dissipation is facilitated by mounting the power module to a heat sink. In such applications, dissipation of heat by the power module to the heat sink may be promoted by including a layer of thermal interface material (TIM) between an outer mounting surface of the power module and a surface of the heat sink. However, a nonuniform thermal interface between the outer mounting surface of the power module and the surface of the heat sink may reduce the reliability and/or lifetime of the power module.

Thus, there is a need for a solution that ensures a uniform thermal interface for efficient heat dissipation by a power module to a heat sink.

### SUMMARY

According to an embodiment of a power module, the power module comprises: a substrate; a power semiconductor die attached to the substrate; an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side; a first type pressing element at the first fastening side and the second fastening side; and a second type pressing element at the first non-fastening side and the second non-fastening side, wherein both types of pressing elements are configured to press against the substrate in a mounted state of the power module, wherein the second type pressing element has a different geometrical structure and/or material composition than the first type pressing element.

According to an embodiment of a method, the method comprises: attaching a power semiconductor die to a substrate; providing an enclosure comprising a first fastening side, a second fastening side opposite the first fastening side, a first non-fastening side, and a second non-fastening side opposite the first non-fastening side, wherein each of the first fastening side and the second fastening side comprises a fastening feature, wherein each of the first non-fastening side and the second non-fastening side intersects the first fastening side and the second fastening side; providing a first type pressing element and a second type pressing element, the second type pressing element having a different geometrical structure and/or material composition than the first type pressing element; and mounting the enclosure to the substrate such that the substrate and the enclosure delimit an interior space in which the power semiconductor die is enclosed, the enclosure presses the first type pressing element against the substrate at the first fastening side and the second fastening side, and the enclosure presses the second type pressing element against the substrate at the first non-fastening side and the second non-fastening side.

According to an embodiment of an electronic assembly, the electronic assembly comprises: a power module mounted to a heat sink, the power module, comprising: a substrate; a power semiconductor die attached to the substrate; an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side; a first type pressing element at the first fastening side and the second fastening side; and a second type pressing element at the first non-fastening side and the second non-fastening side, wherein both types of the pressing elements press against the substrate, wherein the second type pressing element has a different geometrical structure and/or material composition than the first type pressing element.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a perspective view of a power module, according to an embodiment.

FIG. 2 illustrates a side view of a power semiconductor die and a substrate of a power module, according to an embodiment.

FIG. 3 illustrates a side view of an enclosure of a power module, according to an embodiment.

FIGS. 4A-4D illustrate side views of pressing elements of a power module, according to embodiments.

FIG. 5 illustrates a side view of a power semiconductor die, pressing elements, and a substrate of a power module, according to an embodiment.

FIG. 6 illustrates a side view of an enclosure and pressing elements of a power module, according to embodiments.

FIG. 7A illustrates a side view of a power module, according to an embodiment.

FIG. 7B illustrates a top plan view of a power module, according to an embodiment.

FIGS. 8A-8C illustrate side views of an electronic assembly, according to embodiments.

### DETAILED DESCRIPTION

Described herein is a power module formed with first type and second type pressing elements that are configured to press against a substrate of the power module when the power module is in a mounted state (e.g., mounted to a heat sink). The first type pressing elements and second type pressing elements are formed with different geometrical structures (e.g., dimensions, shape) and/or different material compositions. Forming the first type pressing elements and second type pressing elements in this way may enable the pressing forces that the pressing elements place on the substrate to be distributed more evenly between the first type pressing elements and second type pressing elements, potentially improving the uniformity of the force of the substrate on the heat sink and thus improving the uniformity of the thermal interface between the power module and the heat sink. A more uniform thermal interface between the power module and the heat sink may provide more efficient heat dissipation by the power module during operation. Thus, forming the power module with first type and second type pressing elements as disclose herein may improve the performance (e.g., reliability, lifetime) of the power module.

Described next, with reference to the figures, are exemplary embodiments of a power module having first type and second type pressing elements.

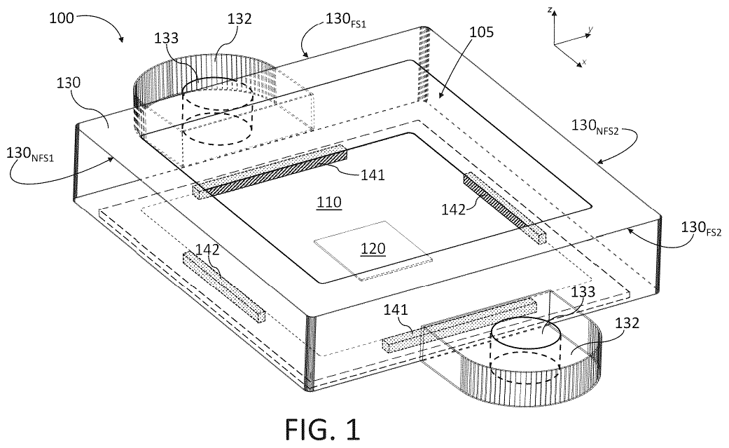

FIG. 1 illustrates a perspective view of a power module 100, according to an embodiment. The power module 100 includes a power semiconductor die 120 attached to a substrate 110. The substrate 110 and an enclosure 130 of the power module 100 delimit an interior space 105 in which the power semiconductor die 120 is enclosed.

The enclosure 130 includes a first fastening side 130_{FS1} and a second fastening side 130_{FS2} opposite the first fastening side 130_{FS1}. Each of the first fastening side 130_{FS1} and the second fastening side 130_{FS2} includes a fastening feature 132 for mounting the power module 100, e.g. to a heat sink (not shown in FIG. 1). In this example, the fastening features 132 are tabs that each extend outward from the first and second fastening sides 130_{FS1} and 130_{FS2} and each include a hole 133 to receive a fastener (e.g., a screw, a clip), although other types of fastening features 132 are contemplated.

The enclosure 130 further includes a first non-fastening side 130_{NFS1} and a second non-fastening side 130_{NFS2} opposite the first non-fastening side 130_{NFS1}. Each of the first non-fastening side 130_{NFS1} and the second non-fastening side 130_{NFS2} intersect the first fastening side 130_{FS1} and the second fastening side 130_{FS2}. In this example, the first non-fastening side 130_{NFS1} and the second non-fastening side 130_{NFS2} are substantially perpendicular to the first fastening side 130_{FS1} and the second fastening side 130_{FS2}, although this is not a requirement. For reference and to aid in the subsequent description, the first and second fastening sides 130_{FS1} and 130_{FS2} are oriented along the y direction, and the first and second non-fastening sides 130_{NFS1} and 130_{NFS2} are oriented along the x direction, although this too is not a requirement.

According to an embodiment, the power module 100 includes a first type pressing element 141 at each of the first fastening side 130_{FS1} and the second fastening side 130_{FS2}, and a second type pressing element 142 at each of the first non-fastening side 130_{NFS1} and the second non-fastening side 130_{NFS2}. In the example of the power module 100 of FIG. 1, the first type pressing elements 141 are oriented longitudinally along each of the first fastening side 130_{FS1} and the second fastening side 130_{FS2} (along the y direction), and the second type pressing elements 142 are oriented longitudinally along each of the first non-fastening side 130_{NFS1} and second non-fastening side 130_{NFS2} (along the x direction), although other orientations of the first type pressing elements 141 and the second type pressing elements 142 are contemplated. Both the first type pressing elements 141 and second type pressing elements 142 are configured to press against the substrate 110 in a mounted state of the power module 100, e.g., when the power module 100 is mounted to a heat sink, as will be illustrated and described later in this disclosure.

According to embodiments described herein, the second type pressing elements 142 have a different geometrical structure and/or material composition than the first type pressing elements 141. Different geometrical structures may include different dimensions, shapes, etc. Different material compositions may result in differences in properties of the first type pressing elements 141 and the second pressing type elements 142, e.g., different hardness, rigidity, elasticity, plasticity, etc. In some instances, forming the power module 100 with first type pressing elements 141 and second type pressing elements 142 having distinct geometrical structures and/or material compositions may compensate for differences in the pressing forces along the fasting sides 130_{FS1}/130_{FS2} and non-fastening sides 130_{NFS1}/130_{NFS2}, for example differences resulting from plastic deformation of the enclosure 130, and may thus distribute the pressing forces on the substrate 110 more evenly between the first type and second type pressing elements 141 and 142 when the power module 100 is in a mounted state. This evened distribution of pressing forces of the first type and second type pressing elements 141 and 142 on the substrate 110 may in turn improve the thermal interface between the power module 100 and a heat sink by increasing the uniformity of pressing forces between the substrate 110 and the heat sink, spreading a thermal interface material (TIM) more evenly when mounting the power module 100 to the heat sink, etc. Thus, including a first type pressing element 141 and a second type pressing element 142 in the power module 100 as described herein may improve heat dissipation by the power module 100 during operation and may improve performance (e.g., reliability, lifetime) of the power module 100.

Described hereafter are further details of the power module 100 and its components, and steps for forming the power module 100.

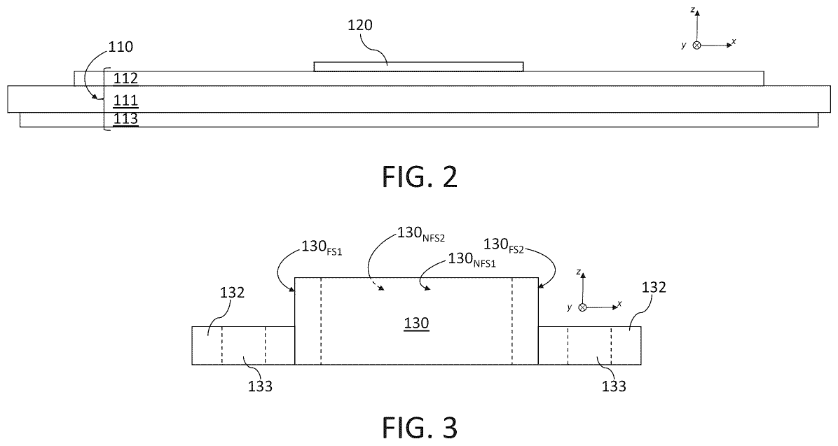

FIG. 2 illustrates a side view of the power semiconductor die 120 and the substrate 110 of the power module 100, according to an embodiment.

Examples of the substrate 110 include a DCB (direct copper bonded) or AMB (active metal brazed) substrate, printed circuit board (PCB), lead frame, or other substrate, e.g., insulated metal substrate (IMS), etc. In the example of FIG. 2, the substrate 110 includes an insulating layer 111 and metallization layers 112 and 113 on opposite sides of the insulating layer 111. The insulating layer 111 may include a ceramic, a polymer such as polyimide, etc. The metallization layers 112 and 113 may each include copper, aluminum, an alloy, etc. The metallization layer 112 may include one or more traces and/or contact pads. The metallization layer 113 may be configured to interface with another component (e.g., a heat sink). Other arrangements of the metallization layers 112 and/or 113, the insulating layer 111, and other metallization and/or insulating layers of the substrate 110 are contemplated.

The power semiconductor die 120 illustrated in FIG. 2 is attached to the metallization layer 112 of the substrate 110. Attaching the power semiconductor die 120 to the substrate 110 may include soldering (e.g., diffusion soldering), brazing, adhering, etc. The power semiconductor die 120 may include one or more devices, including transistors, diodes, resistors, capacitors, and/or other types of active or passive devices. In some examples, the power semiconductor die 120 is a vertical power semiconductor die (e.g., a vertical power transistor die). For a vertical power transistor die, the primary current flow path is between the front and back sides of the power semiconductor die 120 (along the z direction in FIG. 2). In one embodiment, the power semiconductor die 120 is SiC transistor die such as a SiC power MOSFET (metal-oxide-semiconductor field-effect transistor) die. The power semiconductor die 120 may be a Si power MOSFET die, HEMT (high-electron mobility transistor) die, IGBT (insulated-gate bipolar transistor) die, JFET (junction filed-effect transistor) die, etc.

Although not specifically illustrated, the power module 100 may include one or more additional power semiconductor dies 120 attached to the substrate 110. The power semiconductor dies 120 may all be of a similar or identical design (e.g., device type, structure, materials, dimensions, etc.), or some or each of the power semiconductor dies 120 may have different designs. Various arrangements of designs of power semiconductor dies 120 on the substrate 110 are contemplated. The power semiconductor die(s) 120 and/or their constituent devices may be arranged to form all or part of a power electronics circuit such as a DC/AC inverter, a DC/DC converter, an AC/DC converter, an AC/AC converter, a multi-phase inverter, an H-bridge, motor driver, etc. In some examples, a power electronics circuit that includes the power semiconductor die(s) 120 is a half-bridge or full-bridge circuit.

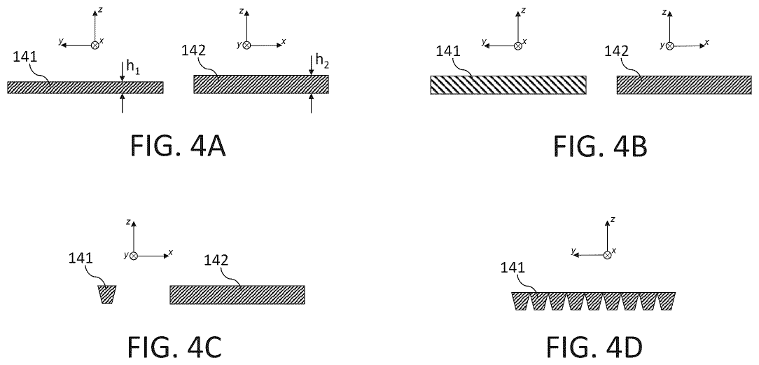

FIG. 3 illustrates a side view of the enclosure 130 of the power module 100, according to an embodiment. The enclosure 130 may be a frame enclosure. A frame enclosure may include one or more pieces of metal, plastic, composite, and/or other suitable material that is structured and arranged to enclose the power semiconductor die 120. Although not specifically illustrated here, the enclosure 130 may include a lid that further delimits the interior space 105 of the power module 100. Alternatively, the power module 100 may include a lid that is attached to the enclosure opposite the substrate 110.

In some examples, the enclosure 130 is a molded enclosure that is formed from a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

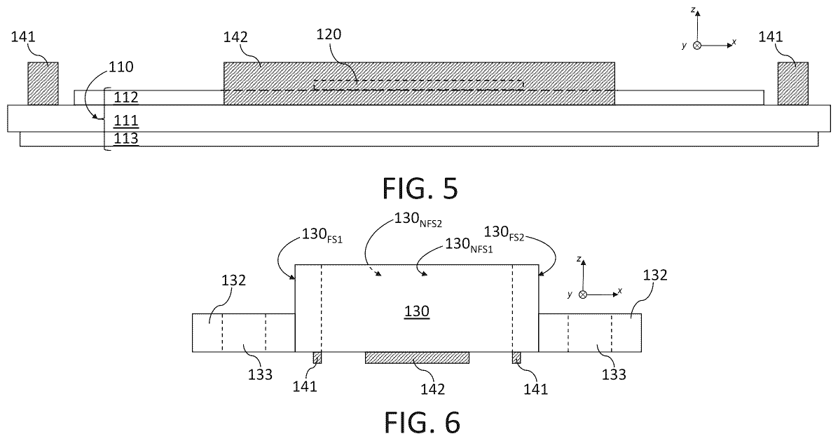

FIGS. 4A-4D illustrate side views of the first type pressing elements 141 and second type pressing elements 142 of the power module 100, according to embodiments. Each of the first type pressing elements 141 and the second type pressing elements 142 may be formed from any suitable material, for example a polymeric material (e.g., a plastic such as a thermoplastic, an elastomer), a composite, etc. In some examples, the first type pressing elements 141 and/or the second type pressing elements 142 are formed from a glue or other adhesive used to mount the enclosure 130 to the substrate. In some examples, the first type pressing elements 141 and/or the second type pressing elements 142 are formed as part of the enclosure 130, e.g., molded with the same material as the rest of the enclosure 130 (e.g., a mold compound) or formed from a different material than the rest of the enclosure 130 (e.g., by co-molding using a process such as two-component or multi-shot injection molding).

FIG. 4A illustrates an example in which the first type pressing elements 141 and the second type pressing elements 142 have different heights in the z direction. Specifically, the second type pressing elements 142 have a greater height h₂ than the height h₁ of the first type pressing element 141. Forming the power module 100 with the second type pressing elements 142 (i.e., those at the non-fastening sides 130_{NFS1}/130_{NFS2} of the enclosure 130, as illustrated in FIG. 1) having a greater height than the first type pressing elements 141 may effectuate the evened distribution of pressing forces of the first type and second type pressing elements 141 and 142 on the substrate 110 by increasing the pressing forces of the second type pressing elements 142 relative to those of the first type pressing elements 141 when the power module 100 is in the mounted state.

FIG. 4B illustrates an example in which the first type pressing elements 141 comprise a first material and the second type pressing elements 142 comprise a second material different than the first material. In this example, the distribution of the pressing forces between the first type pressing elements 141 and the second type pressing elements 142 may be manipulated by forming the first type and second type pressing elements 141 and 142 out of materials that respond differently to forces that are applied when mounting the power module 100 to a heat sink, for example compressive forces between enclosure 130 and the substrate 110. The second type pressing elements 142 may, for example, have a different plasticity (e.g., a higher elastic limit) and/or a different elasticity (e.g., a higher elastic modulus) than the first type pressing elements 141. When mounting the power module 100 having such a configuration of the first type and second type pressing elements 141 and 142, the first type pressing elements 141 may be compressed and deformed elastically and/or plastically to a greater degree than that which would occur with similarly dimensioned pressing elements that are formed from the same material as the second type pressing elements 142. Such increased deformation of the first type pressing elements 141 that is achieved by forming them with a different (e.g., less rigid) material than the second pressing elements 142 may increase the pressing forces of the second type pressing elements 142 relative to those of the first type pressing elements 141 when the power module 100 is in the mounted state. Thus, selecting materials with specific properties, characteristics, etc., for each of the first type pressing elements 141 and the second type pressing elements 142 (e.g., a deformable material for the first type pressing elements 141 and a rigid material for the second type pressing elements 142) may facilitate a more even distribution of the pressing forces of the first type and second type pressing elements 141 and 142 on the substrate 110 when the power module 100 is in the mounted state, potentially improving the thermal interface between the power module 100 and the heat sink.

FIGS. 4C and 4D illustrate examples in which the second type pressing elements 142 have a different shape than the first type pressing elements 141. In the example of FIG. 4C, the first type pressing elements 141 are tapered toward the substrate 110, with the taper in the x direction (e.g., perpendicular to the first and second fastening sides 130_{FS1} and 130_{FS2} of the enclosure 130 as illustrated in FIG. 1). In the example of FIG. 4D, the first type pressing elements 141 each comprise a plurality of segments that are each tapered toward the substrate 110, with the taper in the y direction (e.g., perpendicular to the first and second non-fastening sides 130_{NFS1} and 130_{NFS2} of the enclosure 130). In some examples, the first type pressing elements 141 may be tapered in multiple directions, e.g., having a conical shape. Other shapes are contemplated. Furthermore, although not specifically illustrated, the second type pressing elements 142 may be shaped.

A first type pressing element 141 having a shape, e.g. a taper, as illustrated in FIGS. 4C and 4D may respond differently to forces that are applied when mounting the power module 100 to a heat sink than a pressing element with shape that is similar to the second type pressing elements 142 (e.g., a pressing element without a taper toward the substrate). The first type pressing elements 141 having a shape such as a taper may be compressed and deformed elastically and/or plastically to a greater degree when mounting the power module 100 to a heat sink. Such increased deformation of the first type pressing elements 141 that may be achieved by forming them with a shape that is different from that of the second type pressing elements 142 may increase the pressing forces of the second type pressing elements 142 relative to those of the first type pressing elements 141 when the power module 100 is in the mounted state. Thus, forming each of the first type pressing elements 141 and the second type pressing elements 142 with different shapes may facilitate a more even distribution of the pressing forces of the first type and second type pressing elements 141 and 142 on the substrate 110 when the power module 100 is in the mounted state, potentially improving the thermal interface between the power module 100 and the heat sink.

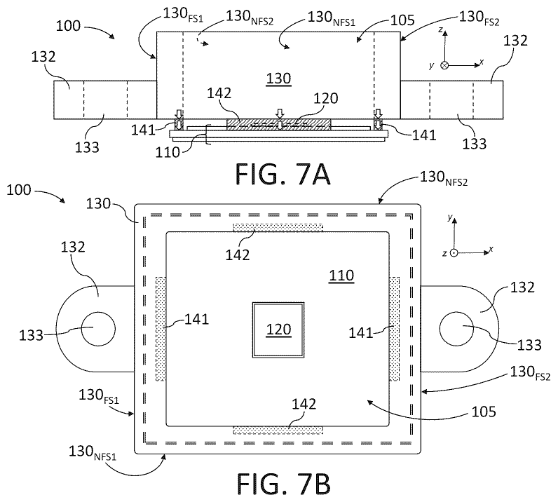

FIG. 5 illustrates a side view of the power semiconductor die 120, the first type pressing elements 141 and second type pressing elements 142, and the substrate 110 of the power module 100, according to an embodiment. In this example, the first type pressing elements 141 and the second type pressing elements 142 are attached to the substrate 110 before mounting the enclosure 130 to the power module 100. Although both the first and second type pressing elements 141 and 142 are illustrated to be attached to the substrate 110, it is contemplated that only the first type pressing elements 141 or only the second type pressing elements 142 may be attached to the substrate 110 before mounting the enclosure 130 to the power module 100.

In some examples, the first type pressing elements 141 and/or the second type pressing elements 142 are glued or otherwise adhered to the substrate 110. As noted previously, the first type pressing elements 141 and/or the second type pressing elements 142 may be formed of a glue or other adhesive that is applied to the substrate 110 and is used to mount the enclosure 130 to the substrate 110.

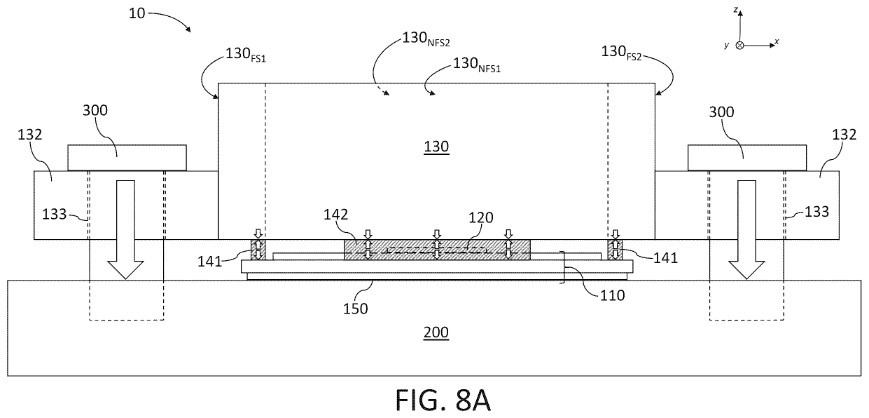

FIG. 6 illustrates a side view of the enclosure 130 and the first type pressing elements 141 and second type pressing elements 142 of the power module 100, according to embodiments. The first type pressing elements 141 and/or the second type pressing elements 142 of this example may be separate bodies from the enclosure 130 that are attached to the enclosure 130 (e.g., by a glue or other adhesive) before mounting the enclosure 130 to the substrate 110. In some examples, the first type pressing elements 141 and/or the second type pressing elements 142 may be formed from a glue or other adhesive that is applied to the enclosure 130 and is used to mount the enclosure 130 to the substrate 110.

Alternatively, the first type pressing elements 141 and/or the second type pressing elements 142 may be a part of the enclosure 130. The first type pressing elements 141 and/or the second type pressing elements 142 may, for example, be molded as features of the enclosure 130 from the same material (e.g., mold compound) that is used to form the rest of the enclosure 130. In other examples, the first type pressing elements 141 and/or the second type pressing elements 142 may be formed integrally with the enclosure 130 and comprise a different material than the enclosure 130, for example by co-molding the enclosure 130 and the first type pressing elements 141 and/or the second type pressing elements 142 using a process such as two-component or multi-shot injection molding.

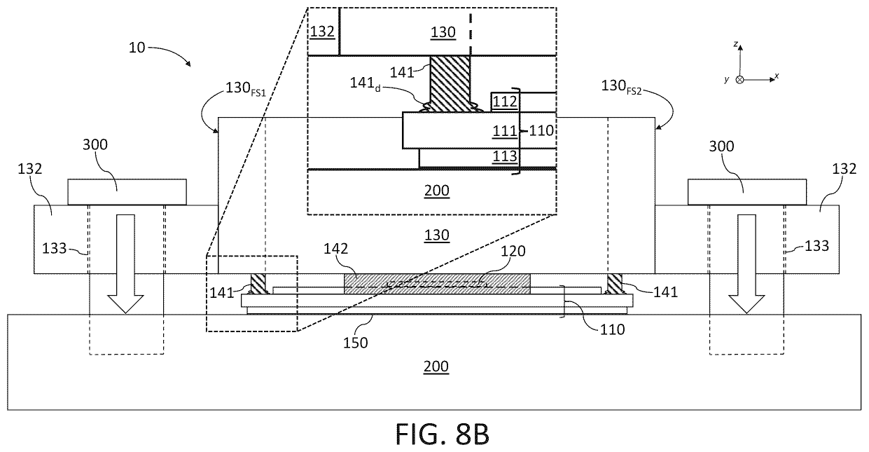

FIGS. 7A and 7B illustrate views of the power module 100 after mounting the enclosure 130 to the substrate 110. FIG. 7A illustrates a side view of the power module 100, according to an embodiment. FIG. 7B illustrates a top plan view of the power module 100, according to an embodiment.

The enclosure 130 is mounted to the substrate 110 such that the substrate 110 and the enclosure 130 delimit the interior space 105 in which the power semiconductor die 120 is enclosed. After mounting the enclosure 130 to the substrate, the enclosure 130 presses the first type pressing element 141 against the substrate 110 at the first fastening side 130_{FS1} and the second fastening side 130_{FS2}, and presses the second type pressing element 142 against the substrate 110 at the first non-fastening side 130_{NFS1} and the second non-fastening side 130_{NFS2}.

The means of mounting the enclosure 130 to the substrate 110 is dependent on the configuration of the first type pressing elements 141 and the second type pressing elements 142. For examples in which the first type pressing elements 141 and/or the second type pressing elements 142 are first attached to the substrate 110 before mounting the enclosure 130 (e.g., as illustrated in FIG. 5), mounting the enclosure 130 to the substrate 110 may comprise attaching (e.g., gluing, adhering) the enclosure 130 to the first type pressing elements 141 and/or the second type pressing elements 142.

For examples in which the first type pressing elements 141 and/or the second type pressing elements 142 are formed from a glue or other adhesive that is used to attach the enclosure 130 to the substrate 110, mounting the enclosure 130 to the substrate 110 may comprise applying the glue or other adhesive to the substrate 110 or the enclosure 130, then placing the enclosure 130 on the substrate 110 with the glue or other adhesive that forms the first type pressing elements 141 and/or the second type pressing elements 142 between the enclosure 130 and the substrate 110.

For examples in which the first type pressing elements 141 and/or the second type pressing elements 142 are attached to the enclosure 130 before mounting the enclosure 130 to the substrate 110 (e.g., as illustrated in FIG. 6), or examples in which the first type pressing elements 141 and/or the second type pressing elements 142 are part of the enclosure 130 or formed integrally with the enclosure 130 (e.g., as illustrated in FIG. 6), mounting the enclosure 130 to the substrate 110 may comprise gluing or attaching the first type pressing elements 141 and/or the second type pressing elements 142 to the substrate 110.

Various combinations of these means for mounting the enclosure 130 to the substrate 110 are contemplated.

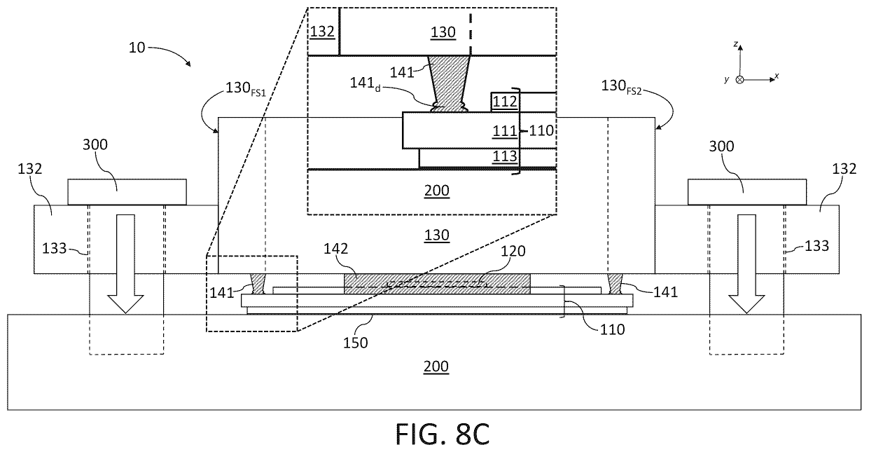

FIGS. 8A-8C illustrate side views of an electronic assembly 10, according to embodiments. The electronic assembly 10 includes the power module 100 mounted to a heat sink 200, with a thermal interface 150 formed between the power module 100 and the heat sink 200. In some examples, the thermal interface 150 includes a thermal interface material (TIM) (not illustrated in FIGS. 8A-8C). In this example, the power module 100 is mounted to the heat sink 200 using fasters 300 (e.g., screws or pins) that are inserted through the holes 133 of the fastening features 132 and into the heat sink 200, although other means of mounting the power module 100 to the heat sink 200 are contemplated.

FIGS. 8A-8C illustrate the power module 100 in a mounted state with the heat sink 200. The heat sink 200 may be passively or actively cooled. In some examples, the heat sink 200 is a solid metallic block such as a baseplate. The heat sink 200 may include one or more channels for carrying a fluid. The heat sink 200 may include fins, ridges, or other surface features for enhancing thermal performance.

As described previously, both types of pressing elements 141 and 142 are configured to press against the substrate 110 in the mounted state of the power module 100, indicated by the lowermost row of arrows in FIG. 8A. The pressing forces of the pressing elements 141 and 142 on the substrate 110 are generated by the forces that the fasteners 300 place on the enclosure 130, specifically on the fastening features 132, indicated by the arrows aligned with each of the fasteners 300. For examples in which the first type pressing elements 141 and/or the second type pressing elements 142 are separate bodies from the enclosure 130, opposing forces are also generated between the first type pressing elements 141 and/or the second type pressing elements 142 and the enclosure 130, with the first type pressing elements 141 and/or the second type pressing elements 142 configured to press against the enclosure 130 in the mounted state, as indicated by the middle and uppermost rows of arrows in FIG. 8A.

As described previously, e.g., with reference to FIGS. 4A-4D, forming the first type pressing elements 141 and the second type pressing elements 142 with different geometrical structures and/or from different material compositions may distribute the pressing forces on the substrate 110 (illustrated by the lowermost row of arrows in FIG. 8A) more evenly between the first type and second type pressing elements 141 and 142 when the power module 100 is in the mounted state as illustrated in FIG. 8A, potentially improving the thermal interface 150 between the power module 100 and the heat sink 200.

FIGS. 8B and 8C illustrate examples in which the first type pressing elements 141 experience some amount of plastic deformation when the power module 100 is mounted to the heat sink 200. FIGS. 8B and 8C each illustrate a region of deformation 141_{d}, although the plastic deformation of the first type pressing elements 141 is not limited to these regions. Purposely deforming the first type pressing elements 141 as illustrated in FIGS. 8B and 8C may increase the pressing forces of the second type pressing elements 142 relative to those of the first type pressing elements 141 and may thus effectuate the evened distribution of pressing forces of the first type and second type pressing elements 141 and 142 on the substrate 110 when the power module 100 is in the mounted state. FIG. 8B illustrates an example in which the plastic deformation may be achieved by forming the first type pressing elements 141 from a different material than the second type pressing elements 142, e.g. as described with reference to FIG. 4B. FIG. 8C illustrates an example in which the plastic deformation may be achieved by forming the first type pressing elements 141 with a different shape than the second type pressing elements, e.g. as described with reference to FIGS. 4C and 4D.

Although the present disclosure is not so limited, the following numbered examples demonstrate one or more aspects of the disclosure.

Example 1. A power module, comprising: a substrate; a power semiconductor die attached to the substrate; an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side; a first type pressing element at the first fastening side and the second fastening side; and a second type pressing element at the first non-fastening side and the second non-fastening side, wherein both types of pressing elements are configured to press against the substrate in a mounted state of the power module, wherein the second type pressing element has a different geometrical structure and/or material composition than the first type pressing element.

Example 2. The power module of example 1, wherein the second type pressing element has a different height, a different shape, a different plasticity, and/or a different elasticity than the first type pressing element.

Example 3. The power module of example 1 or 2, wherein the first type pressing element comprises a first material, and wherein the second type pressing element comprises a second material different than the first material.

Example 4. The power module of any of examples 1 through 3, wherein the second type pressing element has a greater height than the first type pressing element.

Example 5. The power module of any of examples 1 through 4, wherein the second type pressing element has a different shape than the first type pressing element.

Example 6. The power module of any of examples 1 through 5, wherein the second type pressing element has a higher elastic modulus than the first type pressing element.

Example 7. The power module of any of examples 1 through 6, wherein the second type pressing element has a higher elastic limit than the first type pressing element.

Example 8. The power module of any of examples 1 through 7, wherein the first type pressing is tapered toward the substrate.

Example 9. The power module of any of examples 1 through 8, wherein the first type pressing element is a separate body from the enclosure and further configured to press against the enclosure in the mounted state of the power module.

Example 10. The power module of example 9, wherein the first type pressing element is attached to the enclosure.

Example 11. The power module of example 9, wherein the first type pressing element is attached to the substrate.

Example 12. The power module of any of examples 1 through 8, wherein the first type pressing element is a part of the enclosure.

Example 13. The power module of any of examples 1 through 8 or 12, wherein the first type pressing element is formed integrally with the enclosure and comprises a different material than the enclosure.

Example 14. The power module of any of examples 1 through 13, wherein the second type pressing element is a separate body from the enclosure and further configured to press against the enclosure in the mounted state of the power module.

Example 15. The power module of example 14, wherein the second type pressing element is attached to the enclosure.

Example 16. The power module of example 14, wherein the second type pressing element is attached to the substrate.

Example 17. The power module of any of examples 1 through 13, wherein the second type pressing element is a part of the enclosure.

Example 18. The power module of any of examples 1 through 13 or 17, wherein the second type pressing element is formed integrally with the enclosure and comprises a different material than the enclosure.

Example 19. A method, comprising: attaching a power semiconductor die to a substrate; providing an enclosure comprising a first fastening side, a second fastening side opposite the first fastening side, a first non-fastening side, and a second non-fastening side opposite the first non-fastening side, wherein each of the first fastening side and the second fastening side comprises a fastening feature, wherein each of the first non-fastening side and the second non-fastening side intersects the first fastening side and the second fastening side; providing a first type pressing element and a second type pressing element, the second type pressing element having a different geometrical structure and/or material composition than the first type pressing element; and mounting the enclosure to the substrate such that the substrate and the enclosure delimit an interior space in which the power semiconductor die is enclosed, the enclosure presses the first type pressing element against the substrate at the first fastening side and the second fastening side, and the enclosure presses the second type pressing element against the substrate at the first non-fastening side and the second non-fastening side.

Example 20. The method of example 19 wherein the first type pressing element comprises a first material, and wherein the second type pressing element comprises a second material different than the first material.

Example 21. The method of example 19 or 20, wherein the second type pressing element has a greater height than the first type pressing element.

Example 22. The method of any of examples 19 through 21, wherein the second type pressing element has a higher elastic modulus than the first type pressing element.

Example 23. The method of any of examples 19 through 22, wherein the second type pressing element has a higher elastic limit than the first type pressing element.

Example 24. An electronic assembly, comprising: a power module mounted to a heat sink, the power module, comprising: a substrate; a power semiconductor die attached to the substrate; an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side; a first type pressing element at the first fastening side and the second fastening side; and a second type pressing element at the first non-fastening side and the second non-fastening side, wherein both types of the pressing elements press against the substrate, wherein the second type pressing element has a different geometrical structure and/or material composition than the first type pressing element.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a substrate;
a power semiconductor die attached to the substrate;
an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side;
a first type pressing element at the first fastening side and the second fastening side; and
a second type pressing element at the first non-fastening side and the second non-fastening side,
wherein both types of pressing elements are configured to press against the substrate in a mounted state of the power module,
wherein the second type pressing element has a different geometrical structure and/or material composition than the first type pressing element.

2. The power module of claim 1, wherein the second type pressing element has a different height, a different shape, a different plasticity, and/or a different elasticity than the first type pressing element.

3. The power module of claim 1,
wherein the first type pressing element comprises a first material, and
wherein the second type pressing element comprises a second material different than the first material.

4. The power module of claim 1, wherein the second type pressing element has a greater height than the first type pressing element.

5. The power module of claim 1, wherein the second type pressing element has a different shape than the first type pressing element.

6. The power module of claim 1, wherein the second type pressing element has a higher elastic modulus than the first type pressing element.

7. The power module of claim 1, wherein the second type pressing element has a higher elastic limit than the first type pressing element.

8. The power module of claim 1, wherein the first type pressing is tapered toward the substrate.

9. The power module of claim 1, wherein the first type pressing element is a separate body from the enclosure and further configured to press against the enclosure in the mounted state of the power module.

10. The power module of claim 9, wherein the first type pressing element is attached to the enclosure.

11. The power module of claim 9, wherein the first type pressing element is attached to the substrate.

12. The power module of claim 1, wherein the first type pressing element is a part of the enclosure.

13. The power module of claim 1, wherein the first type pressing element is formed integrally with the enclosure and comprises a different material than the enclosure.

14. The power module of claim 1, wherein the second type pressing element is a separate body from the enclosure and further configured to press against the enclosure in the mounted state of the power module.

15. The power module of claim 14, wherein the second type pressing element is attached to the enclosure.

16. The power module of claim 14, wherein the second type pressing element is attached to the substrate.

17. The power module of claim 1, wherein the second type pressing element is a part of the enclosure.

18. The power module of claim 1, wherein the second type pressing element is formed integrally with the enclosure and comprises a different material than the enclosure.

19. A method, comprising:
attaching a power semiconductor die to a substrate;
providing an enclosure comprising a first fastening side, a second fastening side opposite the first fastening side, a first non-fastening side, and a second non-fastening side opposite the first non-fastening side, wherein each of the first fastening side and the second fastening side comprises a fastening feature, wherein each of the first non-fastening side and the second non-fastening side intersects the first fastening side and the second fastening side;
providing a first type pressing element and a second type pressing element, the second type pressing element having a different geometrical structure and/or material composition than the first type pressing element; and
mounting the enclosure to the substrate such that the substrate and the enclosure delimit an interior space in which the power semiconductor die is enclosed, the enclosure presses the first type pressing element against the substrate at the first fastening side and the second fastening side, and the enclosure presses the second type pressing element against the substrate at the first non-fastening side and the second non-fastening side.

20. The method of claim 19,
wherein the first type pressing element comprises a first material, and
wherein the second type pressing element comprises a second material different than the first material.

21. The method of claim 19, wherein the second type pressing element has a greater height than the first type pressing element.

22. The method of claim 19, wherein the second type pressing element has a higher elastic modulus than the first type pressing element.

23. The method of claim 19, wherein the second type pressing element has a higher elastic limit than the first type pressing element.

24. An electronic assembly, comprising:
a power module mounted to a heat sink,
the power module, comprising:
a substrate;
a power semiconductor die attached to the substrate;
an enclosure, the substrate and the enclosure delimiting an interior space in which the power semiconductor die is enclosed, the enclosure comprising a first fastening side and a second fastening side opposite the first fastening side, each of the first fastening side and the second fastening side comprising a fastening feature, the enclosure further comprising a first non-fastening side and a second non-fastening side opposite the first non-fastening side that each intersect the first fastening side and the second fastening side;
a first type pressing element at the first fastening side and the second fastening side; and
a second type pressing element at the first non-fastening side and the second non-fastening side,
wherein both types of the pressing elements press against the substrate,
wherein the second type pressing element has a different geometrical structure and/or material composition than the first type pressing element.
